(19) United States
(12) Patent Application Publication
(10) Pub. No.: US 2018/0348286 A1
(43) Pub. Date: Dec. 6, 2018

(54) METHOD FOR TESTING ELECTRICAL CONNECTION TO MODULE CONNECTOR ON PRINTED CIRCUIT BOARD OR OTHER STRUCTURE AND RELATED APPARATUS

(71) Applicant: Murata Manufacturing Co., Ltd., Nagaokakyo-shi (JP)

(72) Inventor: Hiroyuki Tetsuno, Plano, TX (US)

(21) Appl. No.: 15/612,932

(22) Filed: Jun. 2, 2017

(51) Int. Cl. G01R 31/04; H01R 12/53; H01R 12/70; G01R 31/28

(52) U.S. Cl. CPC G01R 31/04; H01R 12/53; G01R 31/2822; H01R 12/7082; H01R 12/7076

(57) ABSTRACT

An apparatus includes a substrate and a connector mounted on or to the substrate. The connector is configured to be physically coupled to an external component. The apparatus also includes a first electrical path electrically coupling one or more circuit components to the connector. The apparatus further includes a second electrical path electrically coupling the connector to a terminal pad. The second electrical path is physically separate from the first electrical path, and the second electrical path is electrically coupled to the first electrical path by the connector. The terminal pad may be configured to receive, over the second electrical path, a signal provided from the one or more circuit components to the connector over the first electrical path. A presence of the signal from the one or more circuit components at the terminal pad may be indicative of a proper electrical connection between the connector and the one or more circuit components.

### TECHNICAL FIELD

This disclosure is directed generally to the testing of radio frequency (RF) connectors or other module connectors on printed circuit boards or other structures. More specifically, this disclosure relates to a method for testing an electrical connection to a module connector on a printed circuit board or other structure and a related apparatus.

### BACKGROUND

Electronic modules routinely include module connectors that are used to electrically couple the modules to other components of larger devices or systems. For example, wireless radios routinely include radio frequency (RF) connectors that are used to couple the wireless radios to RF antennas. This is a common design for wireless radios and RF antennas used in devices like laptop computers, tablet computers, or wireless smartphones.

During mass production of wireless radios or other electronic modules that include module connectors, the electronic modules are usually tested to ensure that the modules operate as intended. Part of this testing often includes verifying that electrical connections to the module connectors were properly formed and function as intended. For instance, this can include verifying that soldered connections or other connections to the module connectors allow signals to pass to and from the module connectors. This typically requires that a test fixture be physically attached to the module connector of each electronic module being tested.

### SUMMARY

This disclosure provides a method for testing an electrical connection to a module connector on a printed circuit board or other structure and a related apparatus.

In a first embodiment, an apparatus includes a substrate and a connector mounted on or to the substrate. The connector is configured to be physically coupled to an external component. The apparatus also includes a first electrical path electrically coupling one or more circuit components to the connector. The apparatus further includes a second electrical path electrically coupling the connector to a terminal pad. The second electrical path is physically separate from the first electrical path, and the second electrical path is electrically coupled to the first electrical path by the connector.

In a second embodiment, a method includes obtaining a substrate having a first electrical path and a second electrical path, where the second electrical path is physically separate from the first electrical path. The method also includes mounting a connector on or to the substrate, where the connector is configured to be physically coupled to an external component. Mounting the connector includes electrically coupling the connector to one or more circuit components using the first electrical path and electrically coupling the connector to a terminal pad using the second electrical path. The second electrical path is electrically coupled to the first electrical path by the connector.

In a third embodiment, a method includes electrically coupling an electronic module to a testing device. The electronic module includes a substrate and a connector mounted on or to the substrate. The connector is configured to be physically coupled to an external component. The electronic module also includes a first electrical path electrically coupling one or more circuit components to the connector. The electronic module further includes a second electrical path electrically coupling the connector to a terminal pad. The second electrical path is physically separate from the first electrical path, and the second electrical path is electrically coupled to the first electrical path by the connector. The method also includes determining whether a signal provided from the one or more circuit components to the connector over the first electrical path is present at the terminal pad using the testing device.

Other technical features may be readily apparent to one skilled in the art from the following figures, descriptions, and claims.

### BRIEF DESCRIPTION OF THE DRAWINGS

For a more complete understanding of this disclosure, reference is now made to the following description, taken in conjunction with the accompanying drawings, in which:

FIGS. 1A and 1B illustrate an example electronic module having a mechanism for testing an electrical connection to a module connector according to this disclosure;

FIGS. 2A and 2B illustrate an example module connector for an electronic module according to this disclosure;

FIG. 3 illustrates an example system for testing an electrical connection to a module connector of an electronic module according to this disclosure;

FIGS. 4 through 6 illustrate other example electronic modules having a mechanism for testing an electrical connection to a module connector according to this disclosure;

FIG. 7 illustrates an example method for fabricating an electronic module with a mechanism for testing an electrical connection to a module connector according to this disclosure; and

FIG. 8 illustrates an example method for testing an electrical connection to a module connector of an electronic module according to this disclosure.

### DETAILED DESCRIPTION

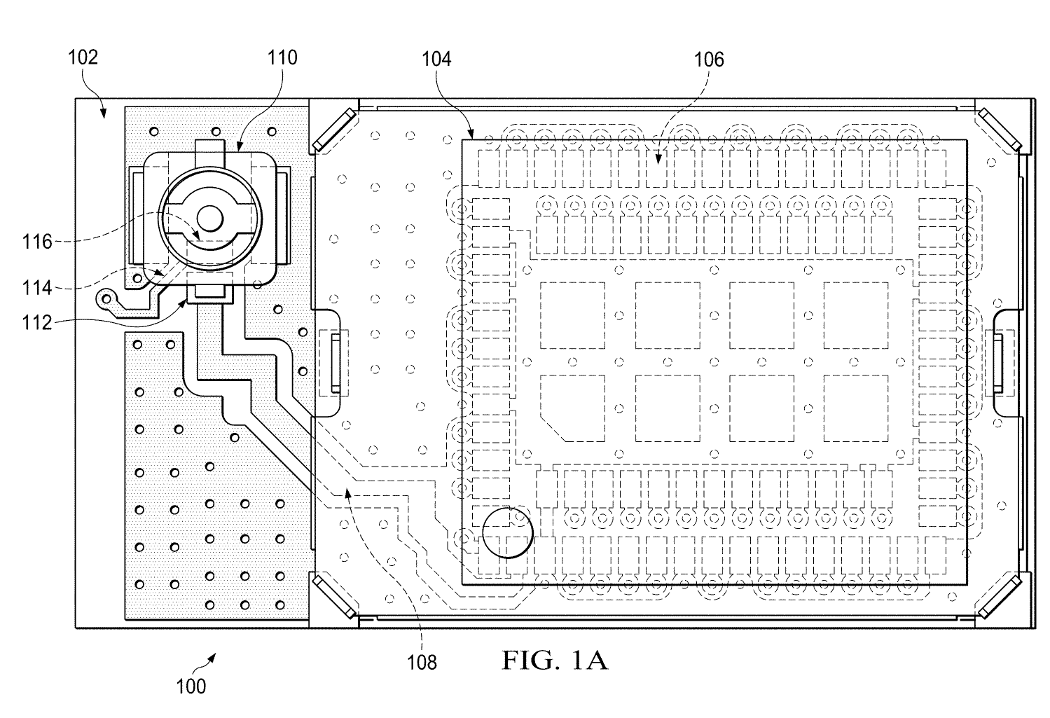

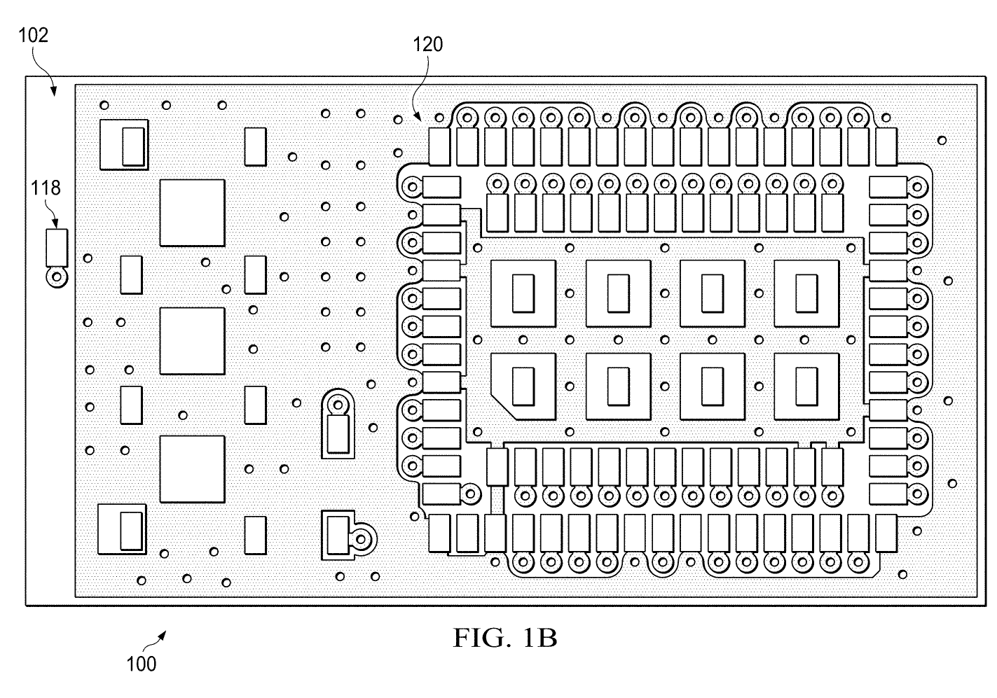

FIGS. 1A through 8, discussed below, and the various embodiments used to describe the principles of the present invention in this patent document are by way of illustration only and should not be construed in any way to limit the scope of the invention. Those skilled in the art will understand that the principles of the invention may be implemented in any type of suitably arranged device or system.

As noted above, electronic modules are often tested to (among other things) ensure that electrical connections to module connectors of the modules function as intended. This typically requires that a test fixture be physically attached to the module connector of each electronic module in order to test the module connectors and the associated electronic modules. However, this can raise various problems. For example, it can be time consuming to physically attach the test fixture to each module connector of each module to be tested. Also, specialized test fixtures may be required for different modules, and each specialized test fixture is typically costly. In addition, the connector of a test fixture is often larger than the module connectors on the modules to be tested. The modules therefore often need to be designed to have a larger space around the module connectors to accommodate the test fixture, which can increase the size and cost of the modules.

This disclosure provides techniques for allowing the testing of module connectors of electronic modules without requiring the physical attachment of test fixtures to the module connectors. Rather, in accordance with this disclosure, an electronic module includes an additional electrical connection to the module connector of that module. The additional electrical connection is separate from an electrical path used to provide a signal or power to the module connector. The additional electrical connection can terminate at a terminal pad or other testing point. During testing, a module tester could be electrically coupled to the terminal pad or other testing point of the module, and the module tester could verify whether an expected signal is present on the terminal pad or other testing point. If so, this is indicative that the same signal is present at the module connector of that module, thereby verifying that the module connector is properly connected to the module.

Among other things, this approach reduces or eliminates the need to physically attach a module tester to each module connector of each module that is being tested. This can greatly increase the speed at which the various modules are actually tested and allows for more automated or completely automated testing of the modules. Moreover, there may be little or no need to use test fixtures that are specifically designed to be physically attached to the module connectors of the modules being tested, which can reduce the expense of the module tester. In addition, the modules to be tested do not need to be designed to accommodate the larger connectors of test fixtures, which can reduce the size and cost of the modules.

FIGS. 1A and 1B illustrate an example electronic module 100 having a mechanism for testing an electrical connection to a module connector according to this disclosure. In particular, FIG. 1A illustrates a top view of the electronic module 100, and FIG. 1B illustrates a bottom view of the electronic module 100.

As shown in FIGS. 1A and 1B, the electronic module 100 includes a substrate 102 on or in which electrical components are formed or placed. The electrical components could be used to provide any desired functionality for the electronic module 100. The substrate 102 denotes any suitable structure that could be used to carry electrical components. In some embodiments, the substrate 102 denotes a printed circuit board (PCB), such as a single-sided, double-sided, or multi-layer printed circuit board. The substrate 102 could also be formed from any suitable material(s), such as rigid or flexible plastic, fiberglass, or epoxy.

The electronic module 100 in this example also includes an integrated circuit chip 104, which for convenience is shown in outline form in FIG. 1A so as to not obscure the underlying portion of the substrate 102. The integrated circuit chip 104 denotes a semiconductor device containing integrated circuitry for performing one or more functions. The integrated circuit chip 104 could support any of a wide variety of functions. For example, in some embodiments, the integrated circuit chip 104 includes circuitry implementing a wireless radio that communicates using one or more wireless protocols. In particular embodiments, the integrated circuit chip 104 includes circuitry supporting wireless communications using both WiFi and BLUETOOTH protocols. Note, however, that the use of an integrated circuit chip 104 in the electronic module 100 is not required, and numerous other or additional circuit components could be used to provide desired functionality in the electronic module 100.

The substrate 102 here includes a number of integrated circuit pads 106, which can be electrically connected to multiple solder bumps or other input/output structures of the integrated circuit chip 104. Each integrated circuit pad 106 includes any suitable structure for forming an electrical connection, such as a copper or other metal pad. Note, however, that other mechanisms could be used to mount the integrated circuit chip 104 on or to the substrate 102. Moreover, the same type of pads 106 could be used to couple to other circuit components, or the pads 106 could be omitted if the integrated circuit chip 104 is not used in the electronic module 100.

The substrate 102 here also includes various electrical paths used to electrically couple components of the electronic module 100 together. This includes an electrical path 108, which can be used to electrically couple the integrated circuit chip 104 (or one or more other electrical components) to a module connector 110. In this example, the electrical path 108 denotes a conductive trace or other conductive path on the substrate 102 that transports electrical signals to or from the integrated circuit chip 104. Each electrical path includes any suitable electrical connection, such as a copper or other conductive trace. Note that the size, shape, and dimensions of the electrical path 108 here are for illustration only.

The module connector 110 denotes an interface that allows for a physical connection of the electronic module 100 to an external device or system. For example, the module connector 110 could denote a radio frequency (RF) connector that is used to couple the electronic module 100 to an RF antenna. The module connector 110 could also denote a power connector used to couple the electronic module 100 to a power supply. The form of the module connector 110 and the type of connection that can be made to the module connector 110 can vary as needed or desired. The module connector 110 generally includes at least one electrical conductor that can be coupled to at least one electrical conductor of a cable or other structure. In this way, the module connector 110 facilitates the formation of an electrical connection to the integrated circuit chip 104 in this example, although electrical connections could be formed with other components in or on the substrate 102 as needed or desired. In this particular example, the substrate 102 includes a connection pad 112 that is electrically coupled to the electrical path 108. The connection pad 112 can also be electrically coupled to the module connector 110, such as by using a soldering or reflow technique. This electrically couples the module connector 110 to the integrated circuit chip 104.

With conventional electronic modules, a test fixture could be physically attached to the module connector 110, and power could be provided to the integrated circuit chip 104. A module tester could then determine whether an RF signal or other signal is received through the module connector 110. As noted above, this approach has a number of shortcomings.

To help overcome these or other problems, the substrate 102 includes at least one additional electrical path 114 and at least one additional connection pad 116. The additional connection pad 116 can be electrically coupled to the module connector 110. The connection pad 116 could be coupled to the module connector 110 in any suitable manner, such as by using a soldering or reflow technique. The additional electrical path 114 electrically couples the module connector 110 to a terminal pad 118. The terminal pad 118 in this example is located on the opposite side of the substrate 102 as shown in FIG. 1B and can be electrically coupled to the additional electrical path 114 through the substrate 102 (such as with one or more conductive vias). However, the terminal pad 118 could be placed in any other suitable location.

The additional connection pad 116 of the substrate 102 is physically separated from the connection pad 112 of the substrate 102. However, both of the connection pads 112 and 116 are electrically connected to the module connector 110, meaning the module connector 110 electrically couples the connection pads 112 and 116 together. Thus, a signal received at the module connector 110 through the connection pad 112 of the substrate 102 would normally pass through the module connector 110 to an external device or system, but the same signal can also pass through the additional connection pad 116 and the additional electrical path 114 to the terminal pad 118. During testing, a module tester could therefore detect the presence of an expected RF signal or other expected signal at the terminal pad 118, and this could be taken as an indication that the module connector 110 is properly mounted on and connected to the electronic module 100. This allows testing of the module connector 110 without requiring that a test fixture be physically attached to the module connector 110.

The electrical path 114 includes any suitable electrical connection, such as a copper or other conductive trace. The size, shape, and dimensions of the electrical path 114 here are for illustration only. Also, each of the connection pads 112 and 116 could have any suitable form, size, shape, and dimensions and could represent any suitable electrical connections to a module connector. The terminal pad 118 includes any suitable structure for forming an electrical connection, such as a copper or other metal pad. The terminal pad 118 is used for testing an electrical connection to a module connector of an electronic module, and the terminal pad 118 is not typically connected to external devices while the electronic module is actually in use.

Note that while the electrical path 114 provides a connection from the module connector 110 on one side of the substrate 102 to a terminal pad 118 on the opposite side of the substrate 102, this is for illustration only. The module connector 110 and the terminal pad 118 could be located on the same side of the substrate 102 if desired. Also note that while a single conductor of the module connector 110 is electrically coupled to a single terminal pad 118 in this example, other approaches could be used. For instance, multiple electrical paths 114 could provide electrical connections between the module connector 110 and multiple terminal pads 118, which could be located on one side of the substrate 102 or on opposite sides of the substrate 102.

As shown in FIG. 1B, a number of additional electrical pads 120 are provided on the bottom of the substrate 102. The additional electrical pads 120 allow for various signals and power to be provided to the integrated circuit chip 104 or other circuit components, such as during testing of the electronic module 100 or during operation of the electronic module 100 in a larger device or system. Note that the number and layout of the additional electrical pads 120 can vary as needed or desired in order to provide signals and power to the components of the electronic module 100. Each of the additional electrical pads 120 includes any suitable structure for forming an electrical connection, such as a copper or other metal pad.

Various other structures in or on the substrate 102 are shown in FIGS. 1A and 1B. These structures relate to specific implementations of the electronic module 100, such as for a wireless radio, and may not be needed or required in other implementations of the electronic module 100.

Although FIGS. 1A and 1B illustrate one example of an electronic module 100 having a mechanism for testing an electrical connection to a module connector 110, various changes may be made to FIGS. 1A and 1B. For example, the electronic module 100 could include any number of each component shown in FIGS. 1A and 1B. Also, while shown as primarily including an integrated circuit chip 104, the electronic module 100 could include any other or additional circuit components for performing one or more desired functions. In addition, while FIGS. 1A and 1B illustrate one example device in which a mechanism for testing an electrical connection to a module connector 110 could be used, this functionality could be used in any other suitable device.

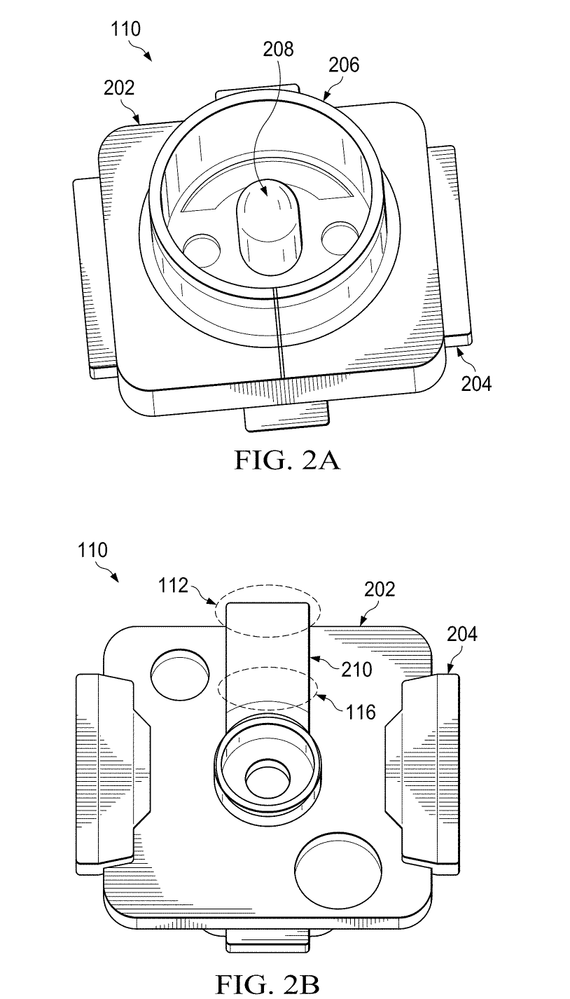

FIGS. 2A and 2B illustrate an example module connector 110 for an electronic module according to this disclosure. In particular, FIG. 2A illustrates a top view of the module connector 110, and FIG. 2B illustrates a bottom view of the module connector 110. For ease of explanation, the module connector 110 of FIGS. 2A and 2B is described as being used in the electronic module 100 of FIGS. 1A and 1B. However, the module connector 110 could be used with any other suitable electronic module, and the electronic module 100 could include any other suitable module connector.

As shown in FIG. 2A, the module connector 110 includes a base 202, ground traces 204, a connector ring 206, and a signal conductor 208. As shown in FIG. 2B, the module connector 110 also includes a signal trace 210, which is electrically connected to the signal conductor 208. The base 202 denotes a structure that holds other components of the module connector 110 and helps to electrically isolate some of those components from one another. For example, the base 202 helps to hold the conductor 208 within and spaced apart from the connector ring 206. The base 202 could be formed from any suitable material(s), such as liquid crystal polymer (LCP) or other insulative material.

The ground traces 204 extend from the base 202 and are used to couple the module connector 110 to an electrical ground. The ground traces 204 could also be used to hold the base 202 away from an underlying structure, such as a PCB or other substrate 102. The ground traces 204 could be formed from any suitable conductive material(s), such as a metal like silver or gold. Note that while this structure allows the module connector 110 to be surface-mounted to a PCB or other substrate 102, other types of mountings could also be used.

The connector ring 206 and the signal conductor 208 form a structure that can be physically coupled to an RF cable or other connection that transports signals to or from the electronic module 100. As a particular example, the connector ring 206 and the signal conductor 208 could form an ultra-miniature coaxial receptacle, although other types of connectors could also be used. The connector ring 206 and the signal conductor 208 could each be formed from any suitable conductive material(s), such as gold plating over other materials like brass or phosphor bronze.

The signal trace 210 denotes a conductive structure that can physically contact or be connected to the connection pad 112 and the additional connection pad 116. The signal trace 210 therefore provides an electrical connection between the connection pads 112, 116 and the signal conductor 208. When the module connector 110 is mounted on or to the substrate 102, the signal trace 210 could be coupled to the electrical path 108 in order to electrically couple the integrated circuit chip 104 (or other circuit components) to the signal conductor 208. The signal trace 210 is also coupled to the additional electrical path 114 in order to electrically couple the terminal pad 118 to the signal conductor 208. The signal trace 210 could be formed from any suitable conductive material(s), such as gold plating over other materials like brass or phosphor bronze.

During conventional testing, a test fixture is physically attached to the module connector 110 in order to form an electrical connection with the signal conductor 208, and the test fixture is used to determine whether an expected signal is present on the signal conductor 208. The connection pad 116 here is also in electrical connection with the signal trace 210 and the signal conductor 208. Because of this, when an electrical connection exists between the connection pad 112 and the signal conductor 208, an electrical connection should also exist between the connection pad 112 and the connection pad 116 through the signal trace 210. As a result, the presence of a signal on the terminal pad 118 is indicative of an acceptable electrical connection between the connection pad 112 and the signal conductor 208. Thus, the terminal pad 118 can be used to test the electrical connection of the electronic module 100 to the module connector 110, without requiring a test fixture to be physically attached to the module connector 110.

Note that while the same signal trace 210 is shown here as being coupled to both connection pads 112, 116, various modifications could be made to the module connector 110. For example, different signal traces could be provided and coupled to different connection pads 112, 116. As a particular example, the elongated shape of the signal trace 210 could be duplicated (such as in the opposite direction), and the ends of the signal traces could be coupled to the connection pads 112, 116.

Although FIGS. 2A and 2B illustrate one example of a module connector 110 for an electronic module, various changes may be made to FIGS. 2A and 2B. For example, other types of module connectors could be used with an electronic module. Also, other structures could be used to create electrical connections to the module connector 110. In general, any module connector and electrical connections to the module connectors could be used, as long as a connection is available to test whether the electrical connection of other circuitry to the module connector was fabricated or is functioning correctly.

FIG. 3 illustrates an example system 300 for testing an electrical connection to a module connector of an electronic module according to this disclosure. For ease of explanation, the system 300 of FIG. 3 is described as being used with the electronic module 100 of FIGS. 1A and 1B having the module connector 110 of FIGS. 2A and 2B. However, the system 300 could be used with any other suitable electronic module and any other suitable module connector.

As shown in FIG. 3, the system 300 includes a test interface 302 that is used to receive and form electrical connections with electronic modules 100 to be tested. For example, each electronic module 100 could be inserted into the test interface 302, such as via a robotic arm or other automated equipment. The test interface 302 includes multiple probes 304 that can contact the pads 118-120 of each electronic module 100. This allows the system 300 to form electrical connections to the electronic modules 100, provide power to the electronic modules 100, and receive and analyze signals from the electronic modules 100. Among other things, the system 300 can analyze whether signals received from the terminal pads 118 of the electronic modules 100 indicate that the electronic modules 100 have acceptable electrical connections to their associated module connectors 110.

The test interface 302 includes any suitable structure configured to receive and retain electronic modules for testing. In this example, the test interface 302 denotes a structure with an opening configured to receive modules under test, although the test interface 302 could have any other suitable structure. Each of the probes 304 includes any suitable structure configured to form an electrical connection to a module under test, such as a spring-loaded metal or other conductive pin.

Although FIG. 3 illustrates one example of a system 300 for testing an electrical connection to a module connector of an electronic module, various changes may be made to FIG. 3. For example, the test interface 302 allows electrical connections to be made to the bottom of a module to be tested, although other electrical connections to a module could also be made. Also, the test interface 302 need not include a recess for receiving the modules under test.

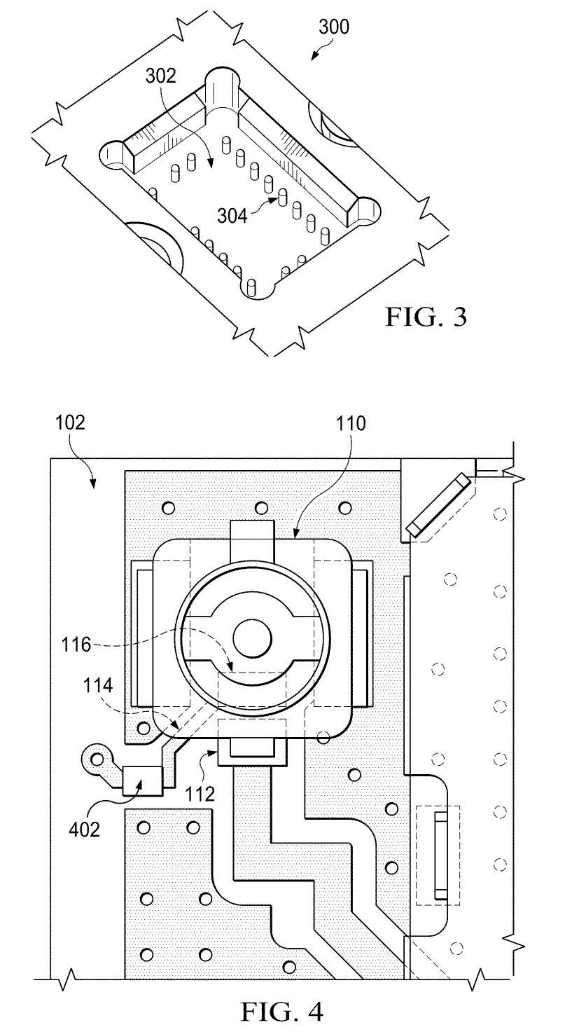

FIGS. 4 through 6 illustrate other example electronic modules having a mechanism for testing an electrical connection to a module connector according to this disclosure. In particular, FIGS. 4 through 6 illustrate other or additional features that could be incorporated into the electronic module 100 described in detail above.

As shown in FIG. 4, a resistor 402 could be formed as part of or could be coupled to the additional electrical path 114. The presence of the electrical path 114 coupled to the additional connection pad 116 and the terminal pad 118 could create some amount of signal loss during normal operation of the electronic module 100. The presence of the resistor 402 along the electrical path 114 can help to reduce or eliminate the transmission of a signal through the electrical path 114 during normal operation of the electronic module 100 while still allowing a signal to travel along the electrical path 114 during testing. The signal strength of the signal during testing would be reduced due to the presence of the resistor 402, but this can be acceptable since it may be the presence of the signal (and not necessarily its signal strength) that indicates a valid electrical connection to the module connector 110. The resistor 402 includes any suitable resistive structure that provides any suitable resistance.

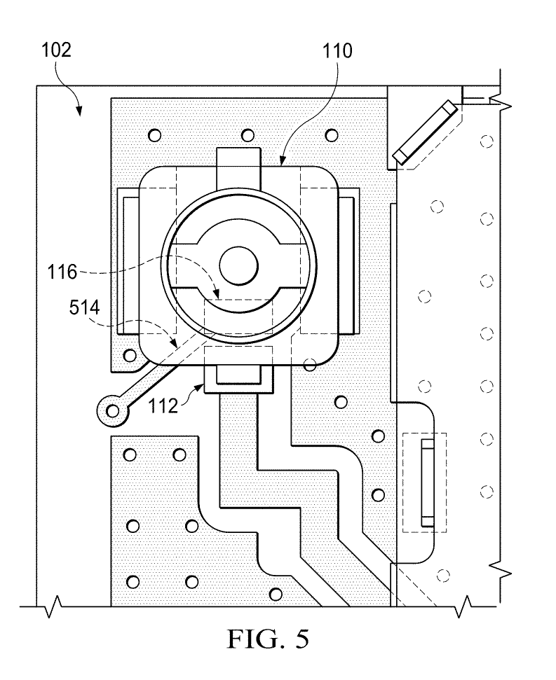

As shown in FIG. 5, the electrical path 114 from FIG. 1A has been replaced with an electrical path 514, which in this example travels straight from the additional connection pad 116 rather than following a bent or curved path as in FIG. 1A. The length of the electrical path coupling the module connector 110 to the terminal pad 118 can contribute to a signal loss, so it may be desirable to reduce or minimize the length of that electrical path. The use of the straight electrical path 514 in FIG. 5 could provide a lower signal loss compared to the bent/curved electrical path 114 in FIG. 1A. To help reduce the signal loss even more, the terminal pad 118 could be moved closer to the additional connection pad 116.

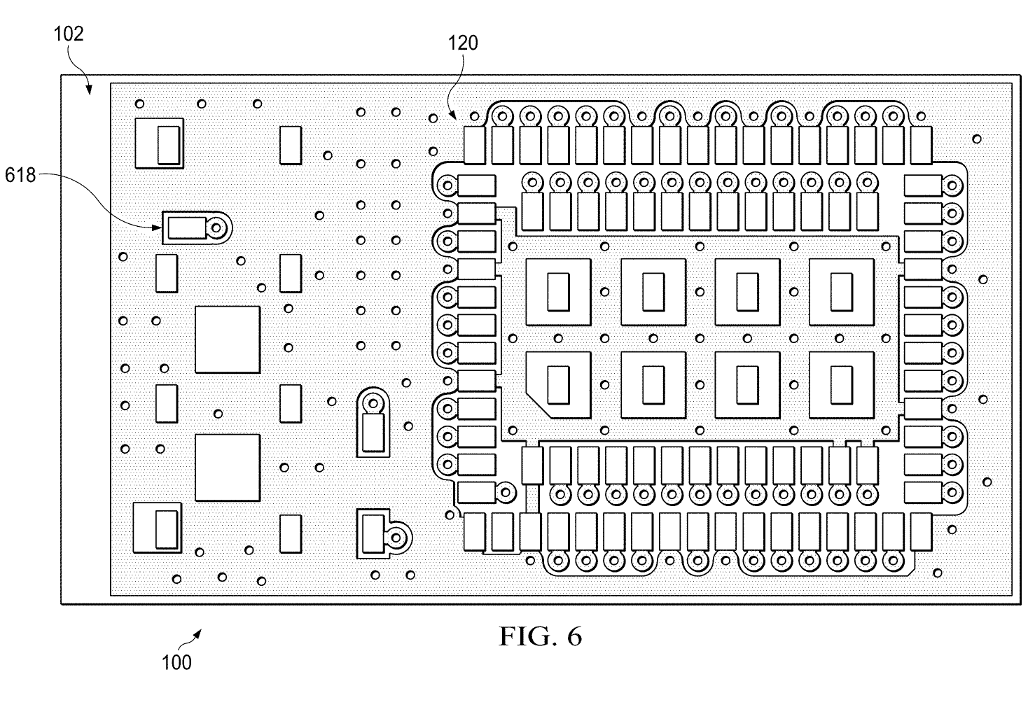

In FIG. 6, the terminal pad 118 has been moved to be located directly opposite the additional connection pad 116. In this case, there may be little or no electrical path formed on the opposing surfaces of the substrate 102, and the electrical path coupling the terminal pad 118 and the additional connection pad 116 could include one or more conductive vias through the substrate 102. This implementation could provide the lowest signal loss for coupling to the terminal pad 118, but it may not be feasible or desirable in some circumstances. For example, if a ground plane extends to the module connector 110, it is possible that a stray capacitance could form between the terminal pad 118 and the ground plane during normal operation of the electronic module 100. In those cases, it may be desirable to move the terminal pad 118 to a location where little or no stray capacitances would form (such as by positioning the terminal pad 118 as shown in FIG. 1B).

Although FIGS. 4 through 6 illustrate other examples of electronic modules having a mechanism for testing an electrical connection to a module connector, various changes may be made to FIGS. 4 through 6. For example, it is possible for features from multiple figures to be combined, such as when the resistor 402 is used with the straight electrical path 514.

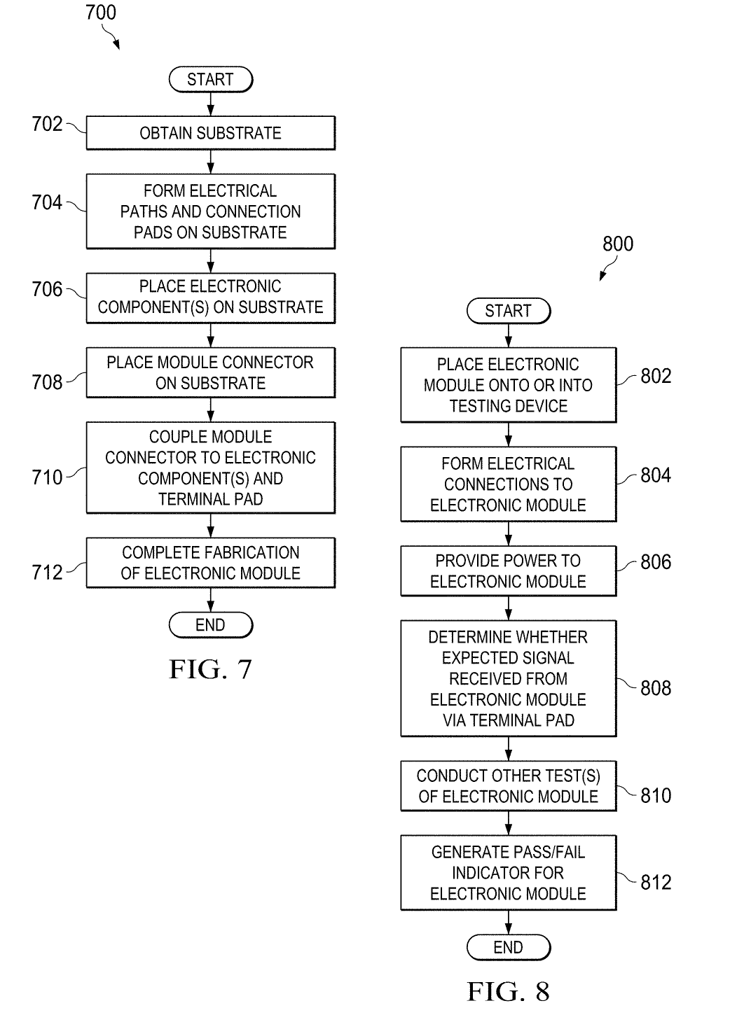

FIG. 7 illustrates an example method 700 for fabricating an electronic module with a mechanism for testing an electrical connection to a module connector according to this disclosure. For ease of explanation, the method 700 of FIG. 7 is described as being used with the electronic module 100 of FIGS. 1A and 1B having the module connector 110 of FIGS. 2A and 2B. However, the method 700 could be used with any other suitable electronic module and any other suitable module connector.

As shown in FIG. 7, a substrate is obtained at step 702, and electrical paths, connection pads, and other conductive structures are formed on the substrate at step 704. This could include, for example, obtaining a PCB or other substrate 102 on which the electrical paths and connection pads can be formed. This could also include depositing metal or other conductive material(s) onto the PCB or other substrate 102 to form the various electrical paths 108, 114 and the various pads 106, 118, 120 on the substrate 102. The conductive material(s) could be deposited in any suitable manner.

One or more electronic components are placed onto the substrate at step 706, at least one module connector is placed onto the substrate at step 708, and the module connector is electrically coupled to the electronic component(s) and a terminal pad at step 710. This could include, for example, soldering or otherwise coupling an integrated circuit chip 104 or other circuit component(s) to the integrated circuit pads 106 on the substrate 102. The circuit components could also be soldered into holes formed through the substrate 102. This could also include soldering or otherwise coupling the ground traces 204 and the signal trace 210 of the module connector 110 to different portions of the substrate 102. The signal trace 210 of the module connector 110 could be soldered or otherwise coupled to the connection pads 112, 116 of the substrate 102. At this point, the module connector 110 should ideally be electrically coupled both to the integrated circuit chip 104 or other circuit component(s) and to the terminal pad 118.

Fabrication of an electronic module is completed at step 712. This could include, for example, coupling any other necessary components to the substrate 102, packaging the structure in a desired manner, or generally performing any other actions needed to create a finished electronic module 100.

Although FIG. 7 illustrates one example of a method 700 for fabricating an electronic module with a mechanism for testing an electrical connection to a module connector, various changes may be made to FIG. 7. For example, while shown as a series of steps, various steps in FIG. 7 could overlap, occur in parallel, occur in a different order, or occur any number of times. Also, while the method 700 was described with respect to a particular electronic module 100 with a particular module connector 110, these components are for illustration only.

FIG. 8 illustrates an example method 800 for testing an electrical connection to a module connector of an electronic module according to this disclosure. For ease of explanation, the method 800 of FIG. 8 is described as being used with the electronic module 100 of FIGS. 1A and 1B having the module connector 110 of FIGS. 2A and 2B. However, the method 800 could be used with any other suitable electronic module and any other suitable module connector.

As shown in FIG. 8, an electronic module is placed onto or into a testing device at step 802, and electrical connections are formed with the electronic module at step 804. This could include, for example, placing the electronic module 100 into the test interface 302 of the testing system 300. This could also include touching the probes 304 of the test interface 302 to the pads 118, 120 of the electronic module 100. Power is provided to the electronic module being tested at step 806. This could include, for example, providing electrical power to the electronic module 100 via one or more of the probes 304 that are electrically coupled to the electronic module 100.

A determination is made whether an expected signal is received from the electronic module being tested through a terminal pad at step 808. This could include, for example, the system 300 determining whether an RF signal or other expected signal is being received through the terminal pad 118 of the electronic module 100 being tested. As noted above, the terminal pad 118 is electrically coupled to the module connector 110, so an expected signal on the terminal pad 118 indicates that the module connector 110 is properly coupled to the integrated circuit chip 104 or other component(s) of the electronic module 100 being tested.

One or more other tests of the electronic module could be conducted at step 810. This could include, for example, the system 300 performing other tests of the electronic module 100 to verify proper operation of the electronic module 100. Of course, the tests performed here can vary depending on the desired functionality of the electronic module 100.

The results of the testing can be used in any suitable manner. For example, a pass/fail indicator for the electronic module could be generated at step 812. This could include, for example, the system 300 generating an output indicating whether the electronic module 100 passed all of the tests. If not, the output could also indicate which test or tests were not passed. The output could be used in any suitable manner, such as by an automated system to remove the electronic module 100 from a normal manufacturing or assembly process for further testing or analysis if a problem with the electronic module 100 has been detected.

Although FIG. 8 illustrates one example of a method 800 for testing an electrical connection to a module connector of an electronic module, various changes may be made to FIG. 8. For example, while shown as a series of steps, various steps in FIG. 8 could overlap, occur in parallel, occur in a different order, or occur any number of times. Also, while the method 800 was described with respect to a particular electronic module 100 with a particular module connector 110, these components are for illustration only.

In some embodiments, various functions described in this patent document are implemented or supported by a computer program that is formed from computer readable program code and that is embodied in a computer readable medium. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable storage device.

It may be advantageous to set forth definitions of certain words and phrases used throughout this patent document. The terms “application” and “program” refer to one or more computer programs, software components, sets of instructions, procedures, functions, objects, classes, instances, related data, or a portion thereof adapted for implementation in a suitable computer code (including source code, object code, or executable code). The term “communicate,” as well as derivatives thereof, encompasses both direct and indirect communication. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present application should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. An apparatus comprising:
a substrate;
a connector mounted on or to the substrate, the connector configured to be physically coupled to an external component;
a first electrical path electrically coupling one or more circuit components to the connector; and
a second electrical path electrically coupling the connector to a terminal pad, the second electrical path physically separate from the first electrical path, the second electrical path electrically coupled to the first electrical path by the connector.

2. The apparatus of claim 1, wherein the terminal pad is configured to receive, over the second electrical path, a signal provided from the one or more circuit components to the connector over the first electrical path.

3. The apparatus of claim 2, wherein a presence of the signal from the one or more circuit components at the terminal pad is indicative of a proper electrical connection between the connector and the one or more circuit components.

4. The apparatus of claim 1, wherein the connector comprises a signal trace that is electrically coupled to the first and second electrical paths.

5. The apparatus of claim 1, wherein the substrate comprises a printed circuit board.

6. The apparatus of claim 1, wherein:
the connector is electrically coupled to an additional pad located on a first side of the substrate; and
the terminal pad is located on an opposing second side of the substrate.

7. The apparatus of claim 6, wherein the terminal pad is located directly across the substrate from the additional pad.

8. The apparatus of claim 1, wherein the second electrical path comprises a straight path extending from the connector.

9. The apparatus of claim 1, wherein the second electrical path includes or is coupled to a resistor.

10. The apparatus of claim 1, wherein the connector comprises a surface-mounted coaxial connector.

11. The apparatus of claim 1, wherein the one or more circuit components comprise an integrated circuit chip.

12. A method comprising:
obtaining a substrate having a first electrical path and a second electrical path, the second electrical path physically separate from the first electrical path; and
mounting a connector on or to the substrate, the connector configured to be physically coupled to an external component;
wherein mounting the connector comprises:
electrically coupling the connector to one or more circuit components using the first electrical path; and
electrically coupling the connector to a terminal pad using the second electrical path, the second electrical path electrically coupled to the first electrical path by the connector.

13. The method of claim 12, wherein the terminal pad is configured to receive, over the second electrical path, a signal provided from the one or more circuit components to the connector over the first electrical path.

14. The method of claim 13, wherein a presence of the signal from the one or more circuit components at the terminal pad is indicative of a proper electrical connection between the connector and the one or more circuit components.

15. The method of claim 12, wherein:
the connector comprises a signal trace; and
mounting the connector comprises coupling the signal trace to the first and second electrical paths.

16. The method of claim 12, wherein:
mounting the connector comprises electrically coupling the connector to an additional pad located on a first side of the substrate; and
the terminal pad is located on an opposing second side of the substrate.

17. The method of claim 16, wherein the terminal pad is located directly across the substrate from the additional pad.

18. The method of claim 12, wherein the second electrical path comprises a straight path extending from the connector.

19. The method of claim 12, wherein the second electrical path includes or is coupled to a resistor.

20. The method of claim 12, further comprising:
forming the first and second electrical paths.

21. A method comprising:
electrically coupling an electronic module to a testing device, the electronic module comprising:
a substrate;
a connector mounted on or to the substrate, the connector configured to be physically coupled to an external component;
a first electrical path electrically coupling one or more circuit components to the connector; and
a second electrical path electrically coupling the connector to a terminal pad, the second electrical path physically separate from the first electrical path, the second electrical path electrically coupled to the first electrical path by the connector; and
determining whether a signal provided from the one or more circuit components to the connector over the first electrical path is present at the terminal pad using the testing device.

22. The method of claim 21, wherein a presence of the signal from the one or more circuit components at the terminal pad is indicative of a proper electrical connection between the connector and the one or more circuit components.

23. The method of claim 21, wherein the connector comprises a signal trace that is electrically coupled to the first and second electrical paths.

24. The method of claim 21, wherein:
the connector is electrically coupled to an additional pad located on a first side of the substrate; and
the terminal pad is located on an opposing second side of the substrate.

25. The method of claim 24, wherein the terminal pad is located directly across the substrate from the additional pad.

26. The method of claim 21, wherein the second electrical path comprises a straight path extending from the connector.

27. The method of claim 21, wherein the second electrical path includes or is coupled to a resistor.
